(19) United States
(12) Patent Application Publication
(10) Pub. No.: US 2024/0421934 A1
(43) Pub. Date: Dec. 19, 2024

(54) NETWORK CODING METHOD AND APPARATUS

(71) Applicant: HUAWEI TECHNOLOGIES CO., LTD., Shenzhen (CN)

(72) Inventors: Wangmei GUO, Xi’an (CN); Jingliang GAO, Xi’an (CN); Zhuolin BIAN, Xi’an (CN); Yongkang LI, Xi’an (CN); Hua CAI, Shanghai (CN); Yichuan YU, Shanghai (CN); Zhenyuan CHEN, Shanghai (CN)

(21) Appl. No.: 18/818,971

(22) Filed: Aug. 29, 2024

Related U.S. Application Data
(63) Continuation of application No. PCT/CN2023/077792, filed on Feb. 23, 2023.

(30) Foreign Application Priority Data
Mar. 14, 2022 (CN) 202210247591.7

(51) Int. Cl. H04L 1/00; H04L 1/1867

(52) U.S. Cl. CPC H04L 1/0009; H04L 1/189

(57) ABSTRACT

A network coding method includes obtaining a data packet group in to-be-sent data packets, processing the data packet group based on a generator matrix of cyclic shift network coding thereby generating encoded data packets, and sending the encoded data packets to a receiving end. The to-be-sent data packets include a plurality of data packet groups. Each data packet group of the plurality of data packet groups includes a plurality of data packets. An element comprised in the generator matrix is a corresponding element in a binary vector field converted from a multi-element field.

### CROSS-REFERENCE TO RELATED APPLICATIONS

This application is a continuation of International Application No. PCT/CN2023/077792, filed on Feb. 23, 2023, which claims priority to Chinese Patent Application No. 202210247591.7, filed on Mar. 14, 2022 the disclosures of the aforementioned applications are hereby incorporated by reference in their entireties.

### TECHNICAL FIELD

One or more embodiments of this application relate to the communication field, and in particular, to a network coding method and apparatus.

### BACKGROUND

In actual wireless communication, a wireless channel is affected by various factors, and a data packet may be lost in a channel transmission process. Two main methods for resolving a problem of a packet loss on a channel include an automatic repeat request (ARQ) and an erasure code (EC). However, in the ARQ, feedback for each data packet occupies a network resource and has a delay. When channel performance is poor, extremely high overheads are caused by the feedback. In the erasure code such as a digital fountain code (DF), reliable data transmission on a packet loss channel in a wireless network of some approaches can be ensured, but more coding redundancy is generated.

Currently, network coding allows a node to perform a forwarding operation after the node processes information received by the node. A node in a network has an encoding capability, and a receiving end performs decoding based on a correlation between encoded data packets. However, an encoding matrix used by a transmitting end to perform random linear network coding is a combination of an upper triangular matrix and a Vandermonde matrix. Linear independence between encoded data packets is ensured, but encoding and decoding complexity of the data packets is high, and an overall transmission delay is large.

### SUMMARY

One or more embodiments of the present application provide a network coding method and apparatus, to reduce encoding and decoding complexity and reduce a transmission delay.

A first aspect of embodiments of this application provides a network coding method. The method includes: obtaining a data packet group in to-be-sent data packets, where the to-be-sent data packets include a plurality of data packet groups, and each data packet group includes a plurality of data packets; processing the data packet group based on a generator matrix of cyclic shift network coding, to generate encoded data packets, where an element included in the generator matrix is an element in a binary vector field converted from a multi-element field; and sending the encoded data packets to a receiving end.

In some embodiments, an execution body is a transmitting end. The transmitting end may select the data packet group from the plurality of to-be-sent data packets; encode the data packets by using the generator matrix, to generate the encoded data packets; and then send the encoded data packets to the receiving end. Because the generator matrix is dimension-reduced from the multi-element field to the binary vector field, a calculation amount of the generator matrix is reduced, encoding and decoding complexity is reduced, and a data transmission delay is reduced.

In some embodiments, the generator matrix is generated by expanding a low density parity check code (low density parity check code, LDPC) basis matrix.

In some embodiments, an encoding and decoding delay is further reduced based on performance of low LDPC encoding and decoding complexity.

In some embodiments, the method further includes: receiving a retransmission sequence number sent by the receiving end; and sending an encoded data packet corresponding to the retransmission sequence number to the receiving end.

In some embodiments, when determining that an encoded data packet is lost, the receiving end may feed back a retransmission sequence number of the lost encoded data packet to the transmitting end, and the transmitting end may send an encoded data packet corresponding to the retransmission sequence number to the receiving end. This improves transmission quality.

In some embodiments, after the receiving a retransmission sequence number sent by the receiving end, the method further includes: recording a quantity of retransmissions of the encoded data packet corresponding to the retransmission sequence number; and when the quantity of retransmissions is greater than a preset threshold, stopping retransmission of the encoded data packet corresponding to the retransmission sequence number.

In some embodiments, the transmitting end may further record the quantity of retransmissions of the encoded data packet. When the quantity of retransmissions of the encoded data packet corresponding to the sequence number fed back by the receiving end is greater than the preset threshold, the transmitting end may stop retransmission, to avoid impact of continuous retransmission on the transmission delay.

In some embodiments, the sending the encoded data packets to a receiving end in the foregoing step includes: when the plurality of data packet groups are all processed by using the generator matrix, sending the encoded data packets corresponding to the plurality of data packet groups to the receiving end.

In some embodiments, the transmitting end sends the encoded data packets to the receiving end only after processing all the to-be-sent data packets to generate the encoded data packets.

A second aspect of embodiments of this application provides a network coding apparatus, to implement the method in any one of the first aspect or the possible implementations of the first aspect. The apparatus includes a corresponding unit or module configured to perform the method. The unit or the module included in the apparatus can be implemented by software and/or hardware. For example, the apparatus may be a network device, or may be a chip, a chip system, or a processor that supports the network device in implementing the foregoing method, or may be a logic module or software that can implement all or some functions of the network device.

A third aspect of embodiments of this application provides a computer device, including a processor. The processor is coupled to a memory. The memory is configured to store instructions. When the instructions are executed by the processor, the computer device is enabled to implement the method in any one of the first aspect or the possible implementations of the first aspect. For example, the computer device may be a network device, or may be a chip or a chip system that supports the network device in implementing the foregoing method.

A fourth aspect of embodiments of this application provides a computer-readable storage medium. The computer-readable storage medium stores instructions. When the instructions are executed by a processor, the method provided in any one of the first aspect or the possible implementations of the first aspect is implemented.

A fifth aspect of embodiments of this application provides a computer program product. The computer program product includes computer program code. When the computer program code is run on a computer, the method provided in any one of the first aspect or the possible implementations of the first aspect is implemented.

### BRIEF DESCRIPTION OF DRAWINGS

FIG. 1 is a diagram of a data packet transmission architecture according to an embodiment of this application;

FIG. 2 is a diagram of a manner of deploying cyclic shift network coding on a base station according to an embodiment of this application;

FIG. 3 is a schematic flowchart of a network coding method according to an embodiment of this application;

FIG. 4 is a schematic flowchart of sending data by a transmitting end according to an embodiment of this application;

FIG. 5 is a diagram of a structure of a network coding apparatus according to an embodiment of this application; and

FIG. 6 is a diagram of a structure of a computer device according to an embodiment of this application.

### DETAILED DESCRIPTION

One or more embodiments of the present application provide a network coding method and apparatus, to reduce encoding and decoding complexity and reduce a transmission delay.

The following describes embodiments of this application with reference to the accompanying drawings. It is clear that the described embodiments are merely some rather than all of embodiments of this application. A person of ordinary skill in the art may learn that, with development of technologies and emergence of a new scenario, technical solutions provided in embodiments of this application are also applicable to a similar technical problem.

In the specification, the claims, and the accompanying drawings of this application, the terms “first”, “second”, and the like are intended to distinguish between similar objects but do not necessarily indicate a specific order or sequence. It should be understood that the data termed in such a way are interchangeable in appropriate cases so that embodiments described herein can be implemented in other orders than the order illustrated or described herein. In addition, the terms “include” and “have” and any other variants thereof are intended to cover a non-exclusive inclusion. For example, a process, a method, a system, a product, or a device that includes a list of steps or units is not necessarily limited to those expressly listed steps or units, but may include other steps or units not expressly listed or inherent to such a process, method, product, or device.

The specific term “example” herein means “used as an example, embodiment or illustration”. Any embodiment described as an “example” is not necessarily explained as being superior to or better than other embodiments.

In addition, to better describe this application, numerous specific details are given in the following specific implementations. A person skilled in the art should understand that this application can also be implemented without some specific details. In some examples, methods, means, elements, and circuits that are well-known to a person skilled in the art are not described in detail, so that the subject matter of this application is highlighted.

First, some concepts provided in embodiments of this application are described.

### Galois Field (GF)

The Galois field is GF(p^{w}), where p is a prime number, and is usually set to 2. To ensure a unit element property, for addition and multiplication operations, GF(2^{w}) uses polynomial operations instead of common addition and multiplication operations.

Particularly, when GF(2¹)=GF(2), because a field includes only two elements, the field is generally referred to as a binary field. Other fields are referred to as multi-element fields. For example, GF(2^{w}) is a finite field including 2^{w} elements. (⋅)⁻¹ represents matrix inversion, and (⋅)^{T} represents transposition.

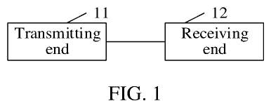

FIG. 1 is a diagram of a data packet transmission architecture according to an embodiment of this application. The architecture includes a transmitting end 11 and a receiving end 12. A data packet is generated and sent by the transmitting end 11, passes through a wireless channel with a specific erasure probability, and finally arrives at the receiving end 12 in a wireless network. The transmitting end 11 encodes the data packet after obtaining the data packet, to be specific, encodes a character, a digit, or another object into a digital code by using a pre-specified method, or converts information or data into a specified electrical pulse signal, where the electrical pulse signal is an encoded data packet. The transmitting end 11 may send the encoded data packet to the receiving end 12, and the receiving end 12 decodes the encoded data packet into original information based on a corresponding method after receiving the encoded data packet. The encoding method may be cyclic shift network coding, and an encoding operation is introduced into a network intermediate node, to improve a throughput, reliability, and security of network transmission, and reduce a transmission delay.

This embodiment of this application may be applied to a single-hop network, a wireless relay multi-hop network, point-to-point multipath transmission, or a satellite relay network. This is not limited herein.

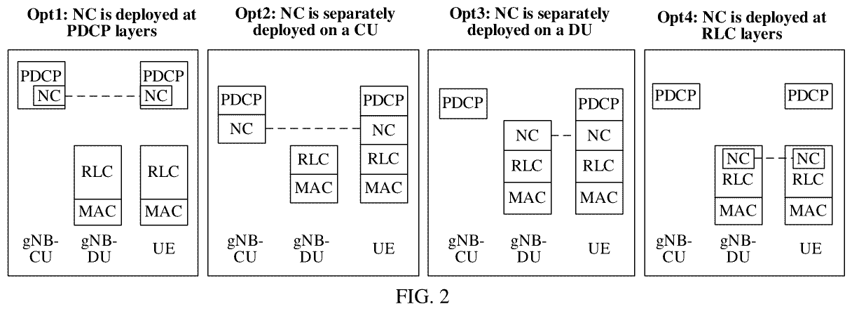

A CU-DU system architecture in a new radio (NR) protocol is used as an example. Refer to FIG. 2. The system architecture includes a next generation NodeB (gNB) or a next generation evolved NodeB (ng-eNB). The gNB is used as an example. User equipment (UE) may communicate with the gNB. The gNB may include one central unit (CU) and one or more distributed units (DUs). One CU may be connected to one or more DUs. Only one CU and one DU are shown in the figure.

A packet data convergence protocol (PDCP) layer is deployed on the CU and the UE. A radio link control (RLC) protocol layer and a media access control (MAC) layer are deployed on the DU and the UE.

PDCP function: A main purpose is to send or receive grouped data of a peer PDCP entity. A sublayer mainly implements the following several functions: internet protocol (IP) header compression and decompression, data and signaling encryption, and signaling integrity protection.

RLC function: A sublayer mainly provides a radio link control function, and provides services such as segmentation, retransmission control, and on-demand transmission for an upper layer.

A higher physical layer, the MAC layer, and the RLC layer that have a high requirement on real-time performance are deployed on the DU for processing, and the PDCP layer that has a low requirement on real-time performance is deployed on the CU for processing.

Cyclic shift network coding (NC) may be deployed on the gNB in a plurality of manners, as shown in FIG. 2: 1. The NC may be deployed at the PDCP layers of the CU and the UE. 2. The NC may be separately deployed on the CU and the UE. 3. The NC may be separately deployed on the DU and the UE. 4. The NC may be deployed at the RLC layers of the DU and the UE. This is not limited in embodiments of this application.

In actual wireless communication, a wireless channel is affected by various factors, and a data packet may be lost in a channel transmission process. Two main methods for resolving a problem of a packet loss on a channel include an automatic repeat request (ARQ) and an erasure code (EC). However, in the ARQ, feedback for each data packet occupies a network resource and has a delay. When channel performance is poor, extremely high overheads are caused by the feedback. In the erasure code such as a digital fountain code (DF), reliable data transmission on a packet loss channel in a wireless network of some approaches can be ensured, but more coding redundancy is generated. Network coding actually allows a node to perform a forwarding operation after the node processes information received by the node. Because a node in a network has an encoding capability, and a receiving end performs decoding based on a correlation between encoded data packets, a decoding success rate is greatly improved, coding redundancy and a quantity of data packet retransmissions are reduced, and a network throughput is improved. However, an encoding matrix used by a transmitting end to perform random linear network coding is a combination of an upper triangular matrix and a Vandermonde matrix. Although linear independence between encoded data packets is ensured, encoding and decoding complexity is high, and an overall transmission delay is large.

To resolve the foregoing problem, an embodiment of this application provides a network coding method. The method is described as follows:

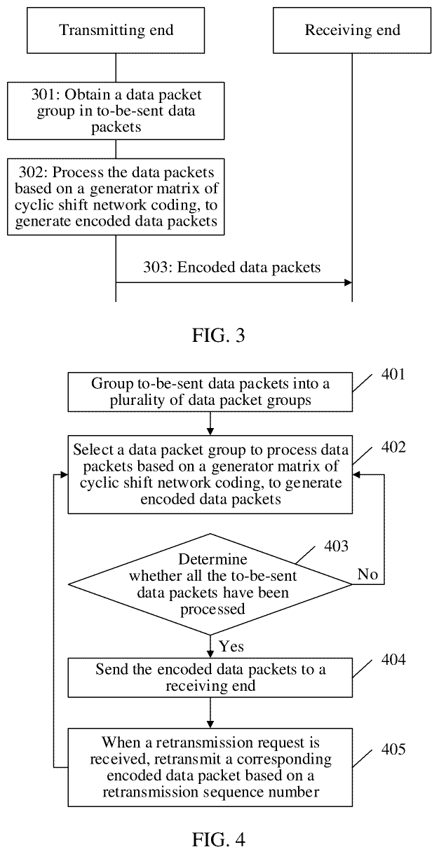

FIG. 3 is a diagram of a network coding method according to an embodiment of this application. The method includes the following steps.

Step 301: A transmitting end obtains a data packet group in to-be-sent data packets.

In this embodiment, data packets in the data packet group may be generated by the transmitting end, or may be generated and transmitted to the transmitting end by a previous node. When the data packets are generated by the transmitting end, the transmitting end may directly obtain the data packets locally. When the data packets are sent by the previous node, the data packets are obtained by the transmitting end by receiving the data packets. The to-be-sent data packets include a plurality of data packet groups, and each data packet group includes a plurality of data packets.

Step 302: The transmitting end processes the data packets based on a generator matrix of cyclic shift network coding to generate encoded data packets, where an element included in the generator matrix is an element in a binary vector field converted from a multi-element field.

In this embodiment, information symbols in the foregoing data packets are all obtained from GF(2^{L}), where L is an even number, and L is a prime number whose primitive element is 2. In this embodiment of this application, GF(2^{L}) is a multi-element field. Because coding construction in the multi-element field increases encoding and decoding complexity, in this embodiment of this application, the multi-element field may be converted into a binary vector field GF(2). An element in the binary vector field is used as an element in the generator matrix of the cyclic shift network coding, and network coding in the binary field is constructed by using a cyclic shift structure characteristic of the cyclic shift network coding, so that a low-complexity shift operation is implemented while approximate performance of network coding in the GF(2^{L}) multi-element field is achieved. In other words, low encoding and decoding complexity is achieved, encoding and decoding time is reduced, and a transmission delay is reduced.

Specifically, after obtaining the data packets, the transmitting end evenly groups all the to-be-sent data packets into groups that each includes k data packets, and uses all-zero packets to supplement data packets that finally cannot be grouped, where a value of k ranges from 1 to a total quantity of all to-be-sent data packets.

For each data packet group, the transmitting end may expand a group of packets to

$$N = ⌈ \frac{k}{I - ε} ⌉ + a packets ,$$

and add obtained encoded data packets to a send queue of the transmitting end, where ┌⋅┐ represents a ceiling operation, and ε represents an erasure probability of a channel in a wireless network selected within a range [0, 0.9]. It can be learned through calculation that, for a receiving end to receive and decode a group of packets, an average value of quantities of packets that the transmitting end needs to send is at least

$$⌈ \frac{k}{1 - ε} ⌉ .$$

a indicates an expansion margin, and can be dynamically adjusted based on system requirements for indicators such as reliability and a packet delay.

In this embodiment, the generator matrix of the cyclic shift network coding may be further obtained by expanding a low density parity check code (LDPC) code basis matrix (where the generator matrix may alternatively be replaced by another decoding algorithm, and an LDPC is used as an example in this embodiment of this application), so that an encoding and decoding delay is reduced based on performance of low LDPC encoding and decoding complexity.

Specifically, an LDPC coding solution is randomly selected to obtain a check matrix H_{(N′-k)×N′} of the LDPC coding solution, and then a basis matrix G_{k×N′} is obtained based on the check matrix. All elements in the matrix are obtained from GF(2). N′>N. In this case, after the transmitting end sends N packets for the first time, sufficient column vectors are still left in G_{k×N′} as encoding coefficients to generate retransmission packets.

C_{L+1} is denoted as a cyclic shift matrix

$$[ \begin{matrix}0 & {I}_{L} \\ 1 & 0\end{matrix} ] ,$$

where I_{L} is a unit matrix whose length of each row and length of each column are L, and for a binary sequence m whose length is L+1, a linear combination mC_{L+1}^{l}(1≤l≤L+1) is obtained by cyclically shifting m rightward by 1 bits. An L×(L+1) matrix G and an (L+1)×L matrix H in a binary field are defined as follows:

$$G = [ \begin{matrix}{I}_{L} & 1\end{matrix} ] , and H = {[ \begin{matrix}{I}_{L} & 1\end{matrix} ]}^{T} .$$

A set is denoted as follows:

Cs={O,GC_{L+1}H,GC_{L+1}²H,GC_{L+1}³H, . . . ,GC_{L+1}^{L+1}H}.

GC_{L+1}^{L+1}H=I_{L}. In this way, a cyclic shift coefficient matrix set C is obtained.

Each element in an LDPC basis matrix G_{k×N′} may be replaced with a matrix in the set Cs according to the following rule, to obtain a generator matrix Ĝ_{kL×N′L} of the cyclic shift network coding, and Ĝ_{kL×N′L} is actually a block matrix. Assuming that Γ_{i,j} represents a coefficient matrix in an i^{th} row and a j^{th} column in Ĝ_{kL×N′L}, and g_{i,j} represents a coefficient in an i^{th} row and a j^{th} column in G_{k×N′},

$${Γ}_{i , j} = \{ \begin{matrix}0 & {g}_{i , j} = 0 \\ 1 & {g}_{i , j} = 1 , j \leq k \\ Any non - zero matrix in Cs & {g}_{i , j} = 0 , j > k\end{matrix} .$$

A block matrix in a j^{th} column in Ĝ_{kL×N′L} corresponds to an encoding coefficient matrix of a j^{th} data packet. During the first time of sending by the transmitting end, the first k data packets are original data packets mᵢ, and in corresponding encoding coefficient matrices Gⱼ, only a j^{th} block is a unit matrix, and the rest are all zero matrices. Subsequent N−K data packets are all encoded data packets, and are generated by using a block matrix G_{k+d}=[Γ_{1,k+d}^{T},Γ_{2,k+d}^{T}, . . . , Γ_{k,k+d}^{T}]^{T} in a (k+d)^{th} column in Ĝ_{kL×N′L} as a coefficient. These encoded data packets may be obtained based on m_{k+d}=Σᵢ₌₁^{k}Γ_{i,k+d}∘mᵢ through calculation, where 1≤i≤k, and 1≤d≤N−k.

For Γ∈Cs, Γ∘mᵢ represents a linear combination of an encoding coefficient matrix and a data packet, and is defined as follows: A packet mᵢ including M bits

$$( \frac{M}{L} GF ( {2}^{L} )$$

symbols) may be expressed as a row vector

$$[ {s}_{i , 1} , {s}_{i , 2} , … , {s}_{i , \frac{M}{L}} ] ,$$

where each row vector s_{i,k} is a row vector that is in GF(2) and whose length is L, and the encoded data packet is

$$Γ ∘ {m}_{j} = [ {s}_{i , 1} Γ , {s}_{i , 2} Γ , … , {s}_{i , \frac{M}{L}} Γ ] .$$

For example, it is assumed that a group of k=7 original data packets need to be sent, the seven original data packets each include four symbols in GF(2³), that is, 12 bits, and a string of 3 bits converted from a j^{th} symbol of an i^{th} packet is expressed as sᵢⱼ. In this case,
m₁=[010 110 101 110]=[s₁₁ s₁₂ s₁₃ s₁₄];
m₂=[010 110 101 110]=[s₂₁ s₂₂ s₂₃ s₂₄];
m₃=[010 110 101 110]=[s₃₁ s₃₂ s₃₃ s₃₄];
m₄=[010 110 101 110]=[s₄₁ s₄₂ s₄₃ s₄₄];
m₅=[010 110 101 110]=[s₅₁ s₅₂ s₅₃ s₅₄];
m₆=[010 110 101 110]=[s₆₁ s₆₂ s₆₃ s₆₄]; and
m₇=[010 110 101 110]=[s₇₁ s₇₂ s₇₃ s₇₄].

This group of packets are encoded into N=11 packets (where

$$N = ⌈ \frac{k}{1 - ε} ⌉ ,$$

and ε=0.35) based on a systematic code, that is, the first seven packets are original packets, and the last four packets are encoded data packets. It is assumed that:

$$G = [ \begin{matrix}1 & 0 & 0 & 1 \\ 0 & 1 & 0 & 1 \\ 0 & 0 & 1 & 1\end{matrix} ] , H = [ \begin{matrix}1 & 0 & 0 & 1 \\ 0 & 1 & 0 & 1 \\ 0 & 0 & 1 & 1\end{matrix} ] , and {C}_{L + 1} = [ \begin{matrix}0 & 1 & 0 & 0 \\ 0 & 0 & 1 & 0 \\ 0 & 0 & 0 & 1 \\ 1 & 0 & 0 & 0\end{matrix} ] .$$

In this case, an encoding coefficient matrix set C may be obtained as follows:

$$\begin{matrix}Cs = \{ O , {GC}_{L + 1} H , {GC}_{L + 1}^{2} H , {GC}_{L + 1}^{3} H , … , {GC}_{L + 1}^{L + 1} H \} \\ = \{ [ \begin{matrix}0 & 0 & 0 \\ 0 & 0 & 0 \\ 0 & 0 & 0\end{matrix} ] , [ \begin{matrix}1 & 1 & 0 \\ 1 & 0 & 1 \\ 1 & 0 & 0\end{matrix} ] , [ \begin{matrix}0 & 1 & 1 \\ 0 & 1 & 0 \\ 1 & 1 & 0\end{matrix} ] , [ \begin{matrix}0 & 0 & 1 \\ 1 & 0 & 1 \\ 0 & 1 & 1\end{matrix} ] , [ \begin{matrix}1 & 0 & 0 \\ 0 & 1 & 0 \\ 0 & 0 & 1\end{matrix} ] \} \\ = \{ O , {C}_{1} , {C}_{2} , {C}_{3} , {C}_{4} \} .\end{matrix}$$

An 8×15 LDPC check matrix H based on an improved PEJ algorithm is used as an example:

$$H = [ \begin{matrix}0 & 0 & 0 & 1 & 0 & 0 & 0 & 1 & 0 & 1 & 0 & 1 & 0 & 0 & 1 \\ 0 & 0 & 1 & 0 & 1 & 0 & 0 & 0 & 0 & 1 & 0 & 0 & 1 & 0 & 0 \\ 0 & 0 & 1 & 0 & 0 & 1 & 1 & 0 & 0 & 0 & 0 & 1 & 0 & 0 & 1 \\ 0 & 1 & 0 & 0 & 0 & 1 & 0 & 0 & 0 & 0 & 1 & 0 & 1 & 0 & 0 \\ 0 & 1 & 0 & 0 & 0 & 0 & 0 & 0 & 1 & 0 & 0 & 1 & 0 & 1 & 0 \\ 0 & 0 & 0 & 1 & 1 & 0 & 0 & 0 & 0 & 0 & 1 & 0 & 0 & 1 & 1 \\ 1 & 0 & 0 & 0 & 0 & 0 & 0 & 0 & 1 & 1 & 1 & 0 & 0 & 0 & 0 \\ 1 & 0 & 0 & 0 & 0 & 0 & 1 & 1 & 0 & 0 & 0 & 0 & 1 & 1 & 0\end{matrix} ] .$$

In addition, a corresponding basis matrix is obtained based on the check matrix:

$$G = [ \begin{matrix}1 & 0 & 0 & 0 & 0 & 0 & 0 & 1 & 1 & 1 & 1 & 0 & 1 & 1 & 0 \\ 0 & 1 & 0 & 0 & 0 & 0 & 0 & 1 & 1 & 1 & 0 & 0 & 1 & 0 & 0 \\ 0 & 0 & 1 & 0 & 0 & 0 & 0 & 0 & 1 & 1 & 0 & 1 & 0 & 0 & 0 \\ 0 & 0 & 0 & 1 & 0 & 0 & 0 & 0 & 0 & 1 & 1 & 1 & 1 & 1 & 1 \\ 0 & 0 & 0 & 0 & 1 & 0 & 0 & 1 & 1 & 1 & 0 & 0 & 0 & 1 & 0 \\ 0 & 0 & 0 & 0 & 0 & 1 & 0 & 0 & 1 & 1 & 0 & 0 & 1 & 1 & 1 \\ 0 & 0 & 0 & 0 & 0 & 0 & 1 & 0 & 0 & 1 & 1 & 0 & 1 & 0 & 1\end{matrix} ] .$$

The LDPC basis matrix is expanded to a generator matrix of cyclic shift vector network coding. An expanded matrix Ĝ_{21×45} is not shown herein due to limited space. Based on the foregoing descriptions, the first seven data packets are original packets, and the last four packets are encoded data packets. A calculation formula is as follows:

mᵢ′=Σᵢ₌₁⁷Γ_{i,j}∘mᵢ,8≤j≤11.

An eighth packet is used as an example. It is assumed that an encoding coefficient matrix (a block matrix in an eighth column in Ĝ_{21×45}, which is written in a row form for convenience) of the eighth packet is as follows:

$$[ \begin{matrix}1 & 1 & 0 & 0 & 1 & 1 & 0 & 0 & 0 & 0 & 0 & 0 & 0 & 1 & 1 & 0 & 0 & 0 & 0 & 0 & 0 \\ 1 & 0 & 1 & 0 & 1 & 0 & 0 & 0 & 0 & 0 & 0 & 0 & 0 & 1 & 0 & 0 & 0 & 0 & 0 & 0 & 0 \\ 1 & 0 & {0}^{′} & 1 & 1 & {0}^{′} & 0 & 0 & {0}^{′} & 0 & 0 & {0}^{′} & 1 & 1 & {0}^{′} & 0 & 0 & {0}^{′} & 0 & 0 & 0 \\ & {Γ}_{1 , 8} & & & {Γ}_{2 , 8} & & & {Γ}_{3 , 8} & & & {Γ}_{4 , 8} & & & {Γ}_{5 , 8} & & & {Γ}_{6 , 8} & & & {Γ}_{7 , 8} & \end{matrix} ] .$$

In this case, an encoded data packet is obtained as follows:

m₈′=Σᵢ₌₁⁷Γ_{i,j}∘mᵢ=Γ_{1,8}∘m₁+ . . . +Γ_{7,8}∘m₇=[s₁₁Γ_{1,8},s₁₂Γ_{1,8},s₂Γ_{1,8},s₁₄Γ_{1,8}]+ . . . +[s₇₁Γ_{7,8},s₇₂Γ_{7,8},s₇₂Γ_{7,8},s₇₄Γ_{7,8}]=[000,101,111,111].

Step 303: The transmitting end sends the encoded data packets to the receiving end.

After generating the encoded data packets, the transmitting end may send the encoded data packets to the receiving end by using the send queue, so that the receiving end may decode the encoded data packets, to obtain the to-be-sent data packets.

Specifically, before sending the encoded data packets, the transmitting end may further determine whether all the data packet groups have been processed to generate encoded data packets. After all the data packet groups are processed, the transmitting end transmits the encoded data packets to the transmitting end one by one.

In this embodiment, a process of processing the encoded data packets by the receiving end may be: calculating a rank r of a coefficient matrix in one group of encoded data packets, and comparing a value of r with a value of kL. If r=kL, that is, an encoding coefficient matrix of the group of packets is full-rank, preliminary decoding may be performed on the received data packets by using an error back propagation (BP) algorithm.

The receiving end receives P (P>N) data packets, where an encoding coefficient matrix of the P data packets forms a kL×PL block matrix that is in GF(2) and whose rank is kL, and each column of the block matrix corresponds to encoding information of one data packet. In a condition of systematic encoding, U data packets in the group are original data packets received by the receiving end, and remaining P−U data packets are encoded data packets m′_{U+1}, . . . , and m′_{P}. The original data packets can be directly decoded. The encoded data packets may be expressed as mⱼ′=Σ_{U+1≤j≤P}Γ_{i,j}∘mᵢ, and an updated encoded data packet set is defined as Φ={m_{U+1}′, . . . , m′_{P}}. A coefficient matrix corresponding to each updated encoded data packet is reset to a (k−U)L×L matrix, and then coefficient matrices of all P−U encoded data packets are combined into a (P−U)L×(P−U)L block matrix, where Γ_{i,j} represents an i^{th} coefficient matrix in a coefficient matrix of an (m′ⱼ)^{th} packet.

An encoded data packet m′ⱼ_{₀} whose coefficient matrix includes only one non-zero coefficient matrix Γᵢ_{₀}_{,j}_{₀} (U+1≤i₀≤k) is selected from Φ, and remaining packets in Φ are updated based on mⱼ_{₀}=Γᵢ_{₀}_{,j}_{₀}⁻¹∘m′ⱼ_{₀} and m′ⱼ_{₀}=m′ⱼ_{₀}_{,j}_{₀}∘mⱼ_{₀}. In this case, a quantity of decoded packets is U≤U′≤k. Then, an encoding coefficient matrix corresponding to mⱼ_{₀} is deleted from a (k−U′)×|Φ|L block matrix, and this step is repeated until each encoded data packet in Φ is generated from at least two original packets.

If Φ is null or |Φ|=1, all packets are successfully decoded. Otherwise, each remaining data packet in Φ is a linear combination of at least two original packets. In this case, if |Φ|>k−U′, it indicates that there are still linearly correlated encoded data packets in Φ, and after the linearly correlated encoded data packets are removed, |Φ|=k−U′. Because the systematic encoding is used, after the foregoing several operations, a value of |Φ| is greatly reduced, and a |Φ|L×|Φ|L block matrix formed by coefficients of |Φ| encoded data packets is still a full-rank binary matrix. In this case, remaining encoded data packets may be directly decoded by using a Gaussian elimination method. At this point, decoding ends.

If the value of |Φ| is still large after the foregoing steps, calculation complexity of directly using the Gaussian elimination method is O(|Φ|³); and when decoding can be performed, complexity required for performing iterative decoding by directly using a check matrix of an LDPC matrix is O(|Φ|), and encoding and decoding complexity is low.

In this embodiment of this application, when determining that an encoded data packet is lost, the receiving end may feed back a retransmission sequence number of the lost encoded data packet to the transmitting end, and the transmitting end may send an encoded data packet corresponding to the retransmission sequence number to the receiving end. The transmitting end may further record a quantity of retransmissions of the encoded data packet. When the quantity of retransmissions of the encoded data packet corresponding to the sequence number fed back by the receiving end is greater than a preset threshold, the transmitting end may stop retransmission to avoid impact of continuous retransmission on a delay.

For example, the transmitting end obtains, in an encoding method of the generator matrix of the cyclic shift network coding, by using an unused block matrix in Ĝ_{kL×N′L}, an encoded data packet corresponding to a received retransmission sequence number, inserts the generated encoded data packet into the send queue of the transmitting end, and increases a quantity of retransmissions corresponding to the encoded data packet by 1.

For example, for steps of sending data by the transmitting end to the receiving end, refer to a schematic flowchart of sending data by the transmitting end shown in FIG. 4. Step 401: Group to-be-sent data packets into a plurality of data packet groups. Step 402: Select a data packet group to process data packets based on a generator matrix of cyclic shift network coding, to generate encoded data packets. Step 403: Determine whether all the to-be-sent data packets have been processed; and if all the to-be-sent data packets have been processed, perform step 404; otherwise, perform step 402. Step 404: Send the encoded data packets to the receiving end. Step 405: When a retransmission request is received, retransmit a corresponding encoded data packet based on a retransmission sequence number.

The foregoing describes the network coding method, and the following describes an apparatus for performing the method.

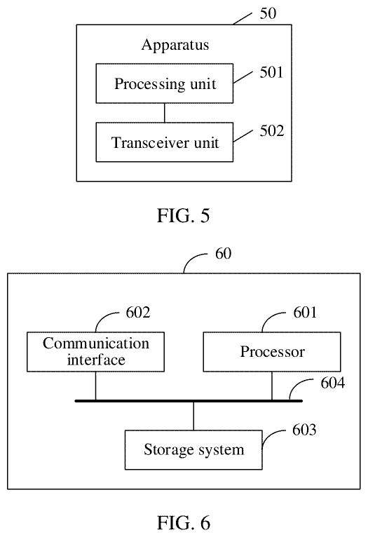

As shown in FIG. 5, an embodiment of this application provides a network coding apparatus. The apparatus 50 includes:
a processing unit 501, configured to: obtain a data packet group in to-be-sent data packets, where the to-be-sent data packets include a plurality of data packet groups, and each data packet group includes a plurality of data packets; and process the data packet group based on a generator matrix of cyclic shift network coding, to generate encoded data packets, where an element included in the generator matrix is an element in a binary vector field converted from a multi-element field; and
a transceiver unit 502, configured to send the encoded data packets to a receiving end.

Optionally, the generator matrix is generated by expanding a low density parity check code LDPC basis matrix.

Optionally, the transceiver unit 502 is further configured to: receive a retransmission sequence number sent by the receiving end; and send an encoded data packet corresponding to the retransmission sequence number to the receiving end.

Optionally, the processing unit 501 is further configured to: record a quantity of retransmissions of the encoded data packet corresponding to the retransmission sequence number; and when the quantity of retransmissions is greater than a preset threshold, stop retransmission of the encoded data packet corresponding to the retransmission sequence number.

Optionally, the transceiver unit 502 is specifically configured to: when the plurality of data packet groups are all processed by using the generator matrix, send encoded data packets corresponding to the plurality of data packet groups to the receiving end.

The processing unit 501 of the apparatus 50 is configured to perform step 301 and step 302 in the method embodiment in FIG. 3, and the determining unit 502 of the apparatus 50 is configured to perform step 303 in the method embodiment in FIG. 3. Details are not described herein again.

FIG. 6 is a diagram of a possible logical structure of a computer device 60 according to an embodiment of this application. The computer device 60 includes a processor 601, a communication interface 602, a storage system 603, and a bus 604. The processor 601, the communication interface 602, and the storage system 603 are connected to each other by using the bus 604. In this embodiment of this application, the processor 601 is configured to control and manage an action of the computer device 60. For example, the processor 601 is configured to perform the steps performed by the transmitting end in the method embodiment in FIG. 3. The communication interface 602 is configured to support the computer device 60 in performing communication. The storage system 603 is configured to store program code and data of the computer device 60.

The processor 601 may be a central processing unit, a general-purpose processor, a digital signal processor, an application-specific integrated circuit, a field programmable gate array or another programmable logic device, a transistor logic device, a hardware component, or any combination thereof. The processor may implement or execute various example logical blocks, modules, and circuits described with reference to content disclosed in this application. Alternatively, the processor 601 may be a combination of processors implementing a computing function, for example, a combination including one or more microprocessors, or a combination of a digital signal processor and a microprocessor. The bus 604 may be a peripheral component interconnect (PCI) bus, an extended industry standard architecture (EISA) bus, or the like. Buses may be classified into an address bus, a data bus, a control bus, and the like. For ease of indication, the bus is indicated by only one bold line in FIG. 6. However, it does not indicate that there is only one bus or only one type of bus.

The transceiver unit 502 in the apparatus 50 is equivalent to the communication interface 602 in the computer device 60, and the processing unit 501 in the apparatus 50 is equivalent to the processor 601 in the computer device 60.

The computer device 60 in this embodiment may correspond to a charging device in the method embodiment in FIG. 2. The communication interface 602 in the computer device 60 may implement functions of the charging device in the method embodiment in FIG. 2 and/or various steps implemented by the charging device in the method embodiment in FIG. 2. For brevity, details are not described herein again.

It should be understood that division of the units in the foregoing apparatus is merely logical function division. During actual implementation, all or some of the units may be integrated into one physical entity, or may be physically separated. In addition, all the units in the apparatus may be implemented in a form of software invoked by a processing element, or may be implemented in a form of hardware; or some units may be implemented in a form of software invoked by a processing element, and some units may be implemented in a form of hardware. For example, each unit may be a separately disposed processing element, or may be integrated into a chip of the apparatus for implementation. In addition, each unit may alternatively be stored in a memory in a form of a program to be invoked by a processing element of the apparatus to perform a function of the unit. In addition, all or some of the units may be integrated, or may be implemented independently. The processing element herein may also be referred to as a processor, and may be an integrated circuit having a signal processing capability. During implementation, steps in the foregoing methods or the foregoing units may be implemented by using a hardware integrated logic circuit in a processor element, or may be implemented in a form of software invoked by a processing element.

In an example, the unit in any one of the foregoing apparatuses may be one or more integrated circuits configured to implement the foregoing methods, for example, one or more application-specific integrated circuits (ASICs), or one or more microprocessors (DSPs), or one or more field programmable gate arrays (FPGAs), or a combination of at least two of these integrated circuit forms. For another example, when the unit in the apparatus is implemented in a form of scheduling a program by a processing element, the processing element may be a general-purpose processor, for example, a central processing unit (CPU) or another processor that can invoke the program. For still another example, the units may be integrated and implemented in a form of a system-on-a-chip (SoC).

In another embodiment of this application, a computer-readable storage medium is further provided. The computer-readable storage medium stores computer-executable instructions. When a processor of a device executes the computer-executable instructions, the device performs the method performed by the transmitting end in the foregoing method embodiment.

In another embodiment of this application, a computer program product is further provided. The computer program product includes computer-executable instructions, and the computer-executable instructions are stored in a computer-readable storage medium. When a processor of a device executes the computer-executable instructions, the device performs the method performed by the transmitting end in the foregoing method embodiment.

It may be clearly understood by a person skilled in the art that, for the purpose of convenient and brief description, for a detailed working process of the foregoing system, apparatus, and unit, refer to a corresponding process in the foregoing method embodiment, and details are not described herein again.

In several embodiments provided in this application, it should be understood that the disclosed system, apparatus, and method may be implemented in other manners. For example, the described apparatus embodiment is merely an example. For example, division into the units is merely logical function division and may be other division during actual implementation. For example, a plurality of units or components may be combined or integrated into another system, or some features may be ignored or not performed. In addition, the displayed or discussed mutual couplings or direct couplings or communication connections may be implemented by using some interfaces. The indirect couplings or communication connections between the apparatuses or the units may be implemented in electronic, mechanical, or other forms.

The units described as separate parts may or may not be physically separate, and parts displayed as units may or may not be physical units, may be located at one position, or may be distributed on a plurality of network units. Some or all of the units may be selected based on actual requirements to achieve the objectives of the solutions of embodiments.

In addition, functional units in embodiments of this application may be integrated into one processing unit, each of the units may exist alone physically, or two or more units are integrated into one unit. The integrated unit may be implemented in a form of hardware, or may be implemented in a form of a software functional unit.

When the integrated unit is implemented in the form of the software functional unit and sold or used as an independent product, the integrated unit may be stored in a computer-readable storage medium. Based on such an understanding, the technical solutions of this application essentially, or the part contributing to the technology of some approaches, or all or some of the technical solutions may be implemented in the form of a software product. The computer software product is stored in a storage medium and includes several instructions for instructing a computer device (which may be a personal computer, a server, a network device, or the like) to perform all or some of the steps of the methods described in embodiments of this application. The foregoing storage medium includes any medium that can store program code, such as a USB flash drive, a removable hard disk, a read-only memory (ROM), a random access memory (RAM), a magnetic disk, or an optical disc.

What is claimed is:

1. A network coding method, comprising:
obtaining a data packet group in to-be-sent data packets, wherein the to-be-sent data packets comprise a plurality of data packet groups, and each data packet group of the plurality of data packet groups comprises a plurality of data packets;
processing the data packet group based on a generator matrix of cyclic shift network coding, thereby generating encoded data packets, wherein an element comprised in the generator matrix is a corresponding element in a binary vector field converted from a multi-element field; and
sending the encoded data packets to a receiving end.

2. The method according to claim 1, wherein the generator matrix is generated by expanding a low density parity check (LDPC) code basis matrix.

3. The method according to claim 1, further comprising:
receiving a retransmission sequence number from the receiving end; and
sending a first encoded data packet corresponding to the retransmission sequence number to the receiving end.

4. The method according to claim 3, wherein after the receiving the retransmission sequence number from the receiving end, the method further comprises:
recording a quantity of retransmissions of the first encoded data packet corresponding to the retransmission sequence number; and
stopping retransmission of the first encoded data packet corresponding to the retransmission sequence number in response to the quantity of retransmissions being greater than a preset threshold.

5. The method according to claim 1, wherein the sending the encoded data packets to the receiving end comprises:
sending a plurality of encoded data packets corresponding to the plurality of data packet groups to the receiving end in response to processing by the generator matrix each of the plurality of data packet groups.

6. A network coding apparatus comprising:
at least one processor; and
one or more memories coupled to the at least one processor, the one or more memories configured to store non-transitory instructions, the at least one processor being configured to execute the non-transitory instructions thereby causing the network coding apparatus to perform operations comprising:
obtaining a data packet group in to-be-sent data packets, wherein the to-be-sent data packets comprise a plurality of data packet groups, and each data packet group of the plurality of data packet groups comprises a plurality of data packets;
processing the data packet group based on a generator matrix of cyclic shift network coding, thereby generating encoded data packets, wherein an element comprised in the generator matrix is a corresponding element in a binary vector field converted from a multi-element field; and
sending the encoded data packets to a receiving end.

7. The network coding apparatus according to claim 6, wherein the generator matrix is generated by expanding a low density parity check (LDPC) code basis matrix.

8. The network coding apparatus according to claim 6, wherein the operations further comprise:
receiving a retransmission sequence number from the receiving end; and
sending a first encoded data packet corresponding to the retransmission sequence number to the receiving end.

9. The network coding apparatus according to claim 8, wherein the operations further comprise:
recording a quantity of retransmissions of the first encoded data packet corresponding to the retransmission sequence number after the receiving the retransmission sequence number from the receiving end; and
stopping retransmission of the first encoded data packet corresponding to the retransmission sequence number in response to the quantity of retransmissions being greater than a preset threshold.

10. The network coding apparatus according to claim 6, wherein the sending the encoded data packets to the receiving end comprises:
sending a plurality of encoded data packets corresponding to the plurality of data packet groups to the receiving end in response to processing by the generator matrix each of the plurality of data packet groups.

11. A computer program product, wherein the computer program product comprises computer program code, and in response to the computer program code being executed by a processor of a computer thereby causes the computer to implement a method, wherein the method comprises:
obtaining a data packet group in to-be-sent data packets, wherein the to-be-sent data packets comprise a plurality of data packet groups, and each data packet group of the plurality of data packet groups comprises a plurality of data packets;
processing the data packet group based on a generator matrix of cyclic shift network coding, thereby generating encoded data packets, wherein an element comprised in the generator matrix is a corresponding element in a binary vector field converted from a multi-element field; and
sending the encoded data packets to a receiving end.

12. The computer program product according to claim 11, wherein the generator matrix is generated by expanding a low density parity check (LDPC) code basis matrix.

13. The computer program product according to claim 11, wherein the method further comprises:
receiving a retransmission sequence number from the receiving end; and
sending a first encoded data packet corresponding to the retransmission sequence number to the receiving end.

14. The computer program product according to claim 13, wherein the method further comprises:
recording a quantity of retransmissions of the first encoded data packet corresponding to the retransmission sequence number after the receiving the retransmission sequence number from the receiving end; and
stopping retransmission of the first encoded data packet corresponding to the retransmission sequence number in response to the quantity of retransmissions being greater than a preset threshold.

15. The computer program product according to claim 11, wherein the sending the encoded data packets to the receiving end comprises:
sending a plurality of encoded data packets corresponding to the plurality of data packet groups to the receiving end in response to processing by the generator matrix each of the plurality of data packet groups.
